(19) United States
(12) Patent Application Publication
(10) Pub. No.: US 2021/0247945 A1
(43) Pub. Date: Aug. 12, 2021

(54) OPERATION DEVICE

(71) Applicant: KABUSHIKI KAISHA TOKAI RIKA DENKI SEISAKUSHO, Aichi (JP)

(72) Inventors: Kohei GOTO, Aichi (JP); Kunitoshi NOGUCHI, Aichi (JP); Shogo YAMAGUCHI, Aichi (JP)

(21) Appl. No.: 17/169,650

(22) Filed: Feb. 8, 2021

(30) Foreign Application Priority Data
Feb. 10, 2020 (JP) 2020-020664

(51) Int. Cl. G06F 3/14; G06F 3/044; G06F 3/02

(52) U.S. Cl. CPC G06F 3/14; G06F 3/0227; G06F 3/044

(57) ABSTRACT

An operation device includes an operating portion including plural adjacent operating regions, plural detection portions that are arranged on the operating portion so as to correspond to the plurality of operating regions to detect contact and each output a detection value, and a determination unit that calculates a calculated value from a sum of the obtained detection values and the largest detection value among the obtained detection values, compares the calculated value to a predetermined threshold value, and thereby decides whether or not to display an image on an electrically connected display device, the image being associated with the detection portion that output the largest detection value.

### CROSS-REFERENCE TO RELATED APPLICATION

The present patent application claims the priority of Japanese patent application No. 2020/020664 filed on Feb. 10, 2020, and the entire contents of Japanese patent application No. 2020/020664 are hereby incorporated by reference.

### TECHNICAL FIELD

The present invention relates to an operation device.

### BACKGROUND ART

A steering wheel switch is known which detects whether or not the switch is operated based on changes in capacitance, pressing force or temperature caused by a driver touching to the switch for performing an operation (see, e.g., Patent Literature 1).

When the driver operates this steering wheel switch, the operational state is displayed on a display unit in response to the operation. Thus, when operating the steering wheel switch, the driver does not need to take eyes off the road in front of the car and move eyes to the steering wheel at hand to see and check the position or type of the switch.

### CITATION LIST

### Patent Literature

Patent Literature 1: JP 2006/347215 A

### SUMMARY OF INVENTION

In case of such a conventional steering wheel switch, users may unintentionally touch the steering wheel switch when manipulating the steering wheel, causing incorrect display on the display unit.

Therefore, it is an object of the invention to provide an operation device which can suppress incorrect display.

According to an embodiment of the invention, an operation device comprises:
an operating portion comprising a plurality of adjacent operating regions;
a plurality of detection portions that are arranged on the operating portion so as to correspond to the plurality of operating regions to detect contact and each output a detection value; and
a determination unit that calculates a calculated value from a sum of the obtained detection values and the largest detection value among the obtained detection values, compares the calculated value to a predetermined threshold value, and thereby decides whether or not to display an image on an electrically connected display device, the image being associated with the detection portion that output the largest detection value.

### Advantageous Effects of Invention

According to the invention, it is possible to suppress incorrect display.

### BRIEF DESCRIPTION OF DRAWINGS

FIG. 1A is a diagram illustrating the inside of a vehicle in which an example of an operation device in an embodiment is arranged.

FIG. 1B is a diagram illustrating an example of the operation device.

FIG. 1C is an example cross-sectional view showing the periphery of a center push switch of the operation device.

FIG. 2 is an example block diagram illustrating the operation device in the embodiment.

FIG. 3A is a diagram illustrating an example of how a user operates the operation device in the embodiment.

FIG. 3B is a diagram illustrating an example of when the user performed a touch operation on a left operating knob.

FIG. 3C is a diagram illustrating an example of when the user unintentionally touched plural operating knobs.

FIG. 4A is a diagram illustrating an example of capacitances obtained when the user performed a touch operation on the left operating knob.

FIG. 4B is a diagram illustrating an example of capacitances obtained when the user unintentionally touched plural operating knobs.

FIG. 4C is a diagram illustrating an image displayed on a display device.

FIG. 5 is a flowchart showing an example of an operation of the operation device in the embodiment.

### DESCRIPTION OF EMBODIMENTS

### SUMMARY OF THE EMBODIMENT

An operation device in the embodiment is generally provided with an operating portion having plural adjacent operating regions, plural detection portions that are arranged on the operating portion so as to correspond to the plural operating regions to detect contact and each output a detection value, and a determination unit that calculates a calculated value from a sum of the obtained detection values and the largest detection value among the obtained detection values, compares the calculated value to a predetermined threshold value, and thereby decides whether or not to display an image, which is associated with the detection portion output the largest detection value, on an electrically connected display device.

The operation device decides whether or not to display the image based on the calculated value that is calculated from the sum of the detection values and the largest detection value. Therefore, decision accuracy is improved and it is thereby possible to suppress incorrect display, as compared to when a decision is made based on only the detection value that is not less than a set threshold.

### Embodiment

### (General Configuration of an Operation Device 1)

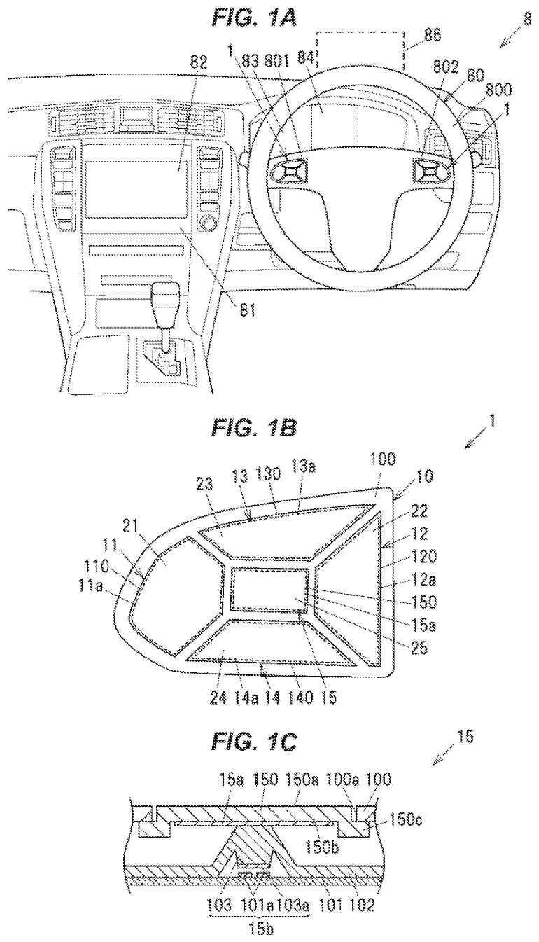

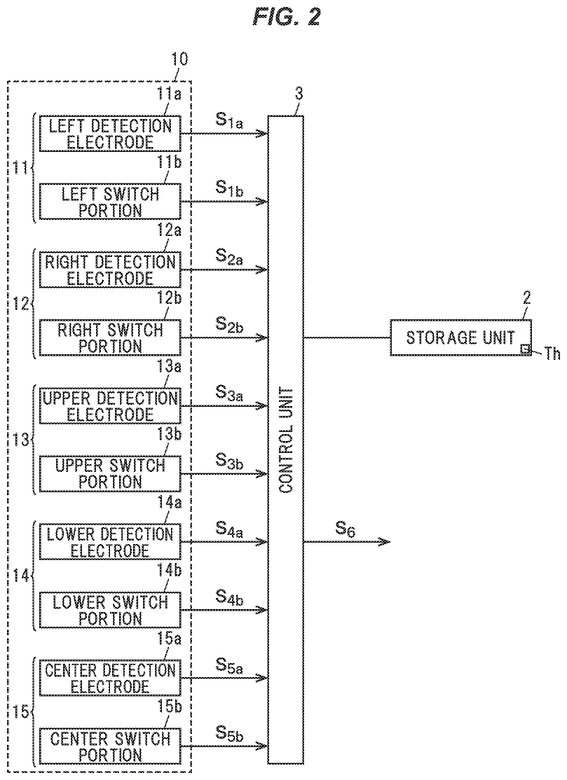

FIG. 1A is a diagram illustrating the inside of a vehicle, FIG. 1B is a diagram illustrating an example of the operation device, and FIG. 1C is an example cross-sectional view showing the operation device. FIG. 2 is an example block diagram illustrating the operation device. In each drawing of the embodiment described below, a scale ratio may be different from an actual ratio. In addition, in FIG. 2, flows of main signals and information are indicated by arrows. Furthermore, the numerical range described as “A-B” means “not less than A and not more than B”.

As an example, the operation devices 1 are installed on left and right spoke portions 801 and 802 of a steering wheel 80 of a vehicle 8, as shown in FIG. 1A. The operation devices 1 are to operate electronic devices mounted on the vehicle 8 and are electromagnetically connected to these electronic devices. As an example, the electronic device is an air conditioner, a navigation device, a music and image reproduction device, or a vehicle control device for controlling automated driving of the vehicle 8 or making various settings of the vehicle 8. The position for arranging the operation device 1 is not limited to the steering wheel 80 and may be a position other than the steering wheel 80, and the operation device 1 may be arranged as an operating portion of the electronic device.

The operation device 1 causes an image, which is related to a push switch detected as being touch-operated, to be displayed on a display device located in a place to which movement of eyes of the user is suppressed. The user can see the image related to a push switch that he/she intends to operate, while suppressing movement of his/her eyes to the operation device 1.

As shown in FIGS. 1A to 2, the operation device 1 is generally provided with an operating portion 10 having plural adjacent operating regions, plural detection portions that are arranged on the operating portion 10 so as to correspond to the plural operating regions to detect contact and each output a detection value, and a control unit 3 as a determination unit that calculates a calculated value from a sum of the obtained detection values and the largest detection value among the obtained detection values, compares the calculated value to a predetermined threshold value, and thereby decides whether or not to display an image, which is associated with the detection portion output the largest detection value, on an electrically connected display device.

The plural operating regions in the present embodiment are, as an example, a left operating region 21-a center operating region 25 as shown in FIG. 1B, but it is not limited thereto.

Meanwhile, the display device is, as an example, at least one of a main display 82, a sub-display 84 and a head-up display 86 mounted on the vehicle 8 as shown in FIG. 1A but it is not limited thereto. The display device in the present embodiment is the head-up display 86, as an example.

The plural detection portions in the present embodiment are plural detection electrodes (=a left detection electrode 11a-a center detection electrode 15a) that constitute a self-capacitance touch sensor, as shown in FIG. 1B. Meanwhile, the detection values are capacitances S₁ₐ-S₅a, as shown in FIG. 2.

The predetermined threshold value is a capacitance threshold value Th stored in a storage unit 2, as shown in FIG. 2. The storage unit 2 is a semiconductor memory arranged on a substrate on which the control unit 3 is also arranged, but it is not limited thereto. The storage unit 2 may be, e.g., a RAM (Random Access Memory) or a ROM (Read Only Memory) (described later) of the control unit 3, or may be an external storage device.

### (Configuration of the Operating Portion 10)

As shown in FIGS. 1B and 1C, the operating portion 10 has operating knobs 110-115 as the plural operating knobs corresponding to the left operating region 21-the center operating region 25 as the plural operating regions and receiving a push operation, and a left switch portion 11b-a center switch portion 15b as the plural switch portions that detect a push operation performed on the operating knobs. The operating portion 10 is provided with a left push switch 11-a center push switch 15 each provided mainly with the operating knob and the switch portion, as shown in FIG. 2.

Functions of the electronic device to be operated are assigned to the left push switch 11- the center push switch 15. That is, the user can give an instruction to execute the assigned function by performing a push operation on the left push switch 11-the center push switch 15.

The operating portion 10 is configured that the operating knob 130, the operating knob 120, the operating knob 140 and the operating knob 110 are arranged around the operating knob 150, clockwise from the upper side of FIG. 1.

Each operating region is provided so as to correspond to the shape of the detection electrode arranged on the operating knob. Thus, the left operating region 21 is a region defined by the left detection electrode 11a arranged on a back surface of the operating knob 110. The right operating region 22 is a region defined by the right detection electrode 12a arranged on a back surface of the operating knob 120. The upper operating region 23 is a region defined by the upper detection electrode 13a arranged on the back surface of the operating knob 130. The lower operating region 24 is a region defined by the lower detection electrode 14a arranged on a back surface of the operating knob 140. Then, the center operating region 25 is a region defined by the center detection electrode 15a arranged on a back surface 150b of the operating knob 150, as shown in FIG. 1C.

In the following description, the configuration of the push switch will be described, taking the center push switch 15 as an example. The center push switch 15 is configured that the center switch portion 15b is turned from an OFF state to an ON state by a push operation performed on a front surface 150a of the operating knob 150 which is formed using a resin material.

The operating knob 150 is arranged so that the front surface 150a is exposed through an opening 100a formed on a bezel 100 of the operation device 1. In addition, the operating knob 150 has a stopper 150c that protrudes from the periphery and prevents from slipping-off through the opening 100a.

The center switch portion 15b is generally provided with a fixed electrode 101a provided on a substrate 101, and a rubber dome 103 provided on a rubber sheet 102. The fixed electrode 101a is formed using a conductive metal material and has a slit at a center. In the state before the push operation, left and right of the fixed electrode 101a as viewed in FIG. 1C are not conducted to each other due to the slit.

The rubber sheet 102 has plural rubber domes 103 which are formed so as to correspond to the left push switch 11-the center push switch 15. The rubber sheet 102 is formed using an insulating rubber material. However, a movable electrode 103a on a top of the rubber dome 103 is formed using a conductive rubber material. Therefore, when a push operation is performed on the center push switch 15, electricity is conducted through the fixed electrode 101a due to contact between the fixed electrode 101a and the movable electrode 103a and the center switch portion 15b is turned from the OFF state to the ON state.

The center push switch 15 is configured that the center switch portion 15b when turned to the ON state outputs a switch signal S_{5b} to the control unit 3. Likewise, when a push operation is performed on the left push switch 11-the lower push switch 14, the left switch portion 11b-the lower switch portion 14b output switch signals S_{1b} to S_{4b} to the control unit 3.

The left detection electrode 11a-the center detection electrode 15a are formed using a conductive metal material such as copper. The left detection electrode 11a-the center detection electrode 15a detect capacitances formed between themselves and an operating finger in contact with surfaces of the operating knobs 110-150 and output them as the capacitances S₁ₐ-S₅ₐ to the control unit 3.

### (Configuration of the Control Unit 3)

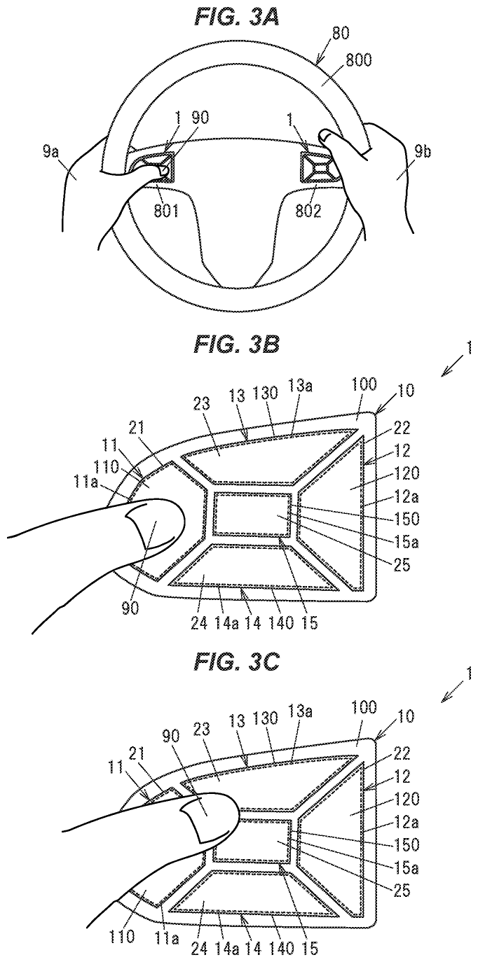

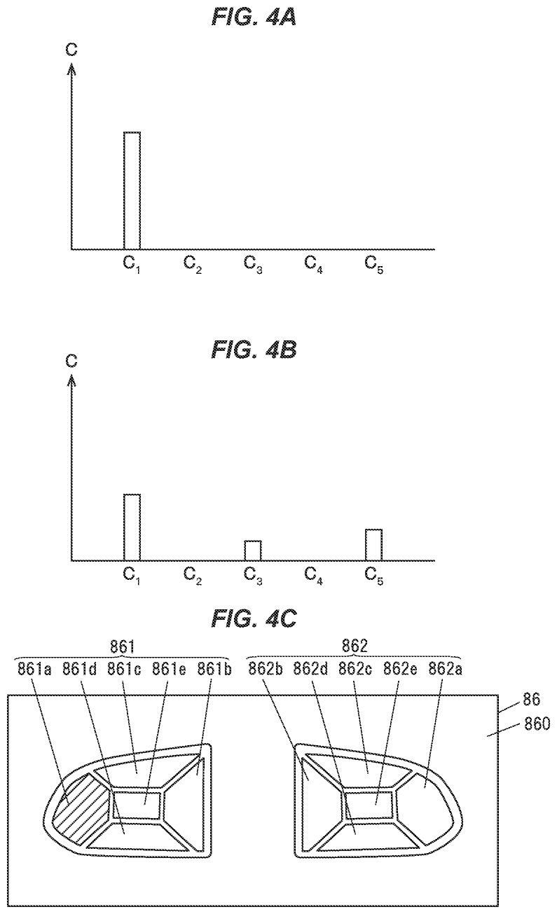

FIG. 3A is a diagram illustrating an example of when a user holding the steering wheel operates the operation device, FIG. 3B is a diagram illustrating an example of when a touch operation is performed on the left operating knob, and FIG. 3C is a diagram illustrating an example of when the user unintentionally touched plural operating knobs. FIG. 4A is a diagram illustrating an example of capacitances obtained when a touch operation is performed on the left operating knob shown in FIG. 3B, FIG. 4B is a diagram illustrating an example of capacitances obtained when a touch operation is performed on the plural operating knobs shown in FIG. 3C, and FIG. 4C is a diagram illustrating an example of an image displayed on the display device. In FIGS. 4A and 4B, the horizontal axis indicates the detection electrodes and the vertical axis indicates capacitance C.

The control unit 3 is, e.g., a microcomputer composed of a CPU (Central Processing Unit) performing calculation and processing, etc., of the acquired data according to a stored program, and a RAM and a ROM as semiconductor memories, etc. The ROM stores, e.g., a program for operation of the control unit 3. The RAM is used as, e.g., a storage area for temporarily storing calculation results, etc. The control unit 3 also has, inside thereof, a means for generating a clock signal, and operates based on the clock signal.

When a touch operation is detected based on the capacitances S₁ₐ-S₅ₐ acquired from the left detection electrode 11a-the center detection electrode 15a of the left push switch 11- the center push switch 15, the control unit 3 generates operation information S₆ including information of the push switch detected as being touch-operated, and outputs the operation information S₆ to the connected electronic device.

Meanwhile, when a push operation is detected based on the switch signals S_{1b} to S_{5b} acquired from the left switch portion 11b-the center switch portion 15b of the left push switch 11-the center push switch 15, the control unit 3 generates the operation information S₆ including information of the push switch detected as being push-operated, and outputs the operation information S₆ to the connected electronic device.

The user holds the periphery of the spoke portions 801 and 802 of the steering wheel 80 using mainly a left hand 9a and a right hand 9b and operates the operation device 1 with a thumb 90, as shown in FIGS. 3A and 3B.

Since the user constantly manipulates the steering wheel 80 during driving, the thumb 90 may unintentionally touch the operation device 1 as shown in FIG. 3C. In addition, when operating the operation device 1 while suppressing movement of eyes, the user may unintentionally perform a touch operation on plural operating regions also as shown in FIG. 3C.

The control unit 3 performs the following control process to prevent a touch operation not intended by the user from causing the image to be displayed.

The image here is, e.g., an image 860 shown in FIG. 4C. This image 860 is an image displayed on the head-up display 86 and includes an image 861 and an image 862 that represent the left push switches 11 to the center push switches 15 arranged on left and right of the steering wheel 80. The image 861 and the image 862 are symmetric with respect to a line.

The image 860 is displayed when a touch operation is detected, in such a manner that a position of the push switch detected as being touched is displayed differently from other images. In FIG. 4C, hatching is used to make it being displayed differently from the other images. The image 861 has images 861a-861e that represent the left push switch 11-the center push switch 15 arranged on the spoke portion 801. The image 862 has images 862a-862e that represent the left push switch 11-the center push switch 15 arranged on the spoke portion 802.

As a modification, the image 860 may be already displayed on the head-up display 86 before a touch operation, and detection of a touch operation causes a corresponding image to be displayed differently from the other images.

The control unit 3 is configured to cause the image to be displayed when the calculated value obtained by dividing the largest capacitance by the sum of capacitances is not less than the capacitance threshold value Th.

The control unit 3 is also configured to not cause the image to be displayed when the calculated value obtained by dividing the largest capacitance by the sum of capacitances is less than the capacitance threshold value Th.

In particular, a calculated value C_{A} is obtained by the following equation (1):

Calculated value C_{A}={Cₘₐₓ/(C₁+C₂+C₃+C₄+C₅)}×100 (1)

where C₁ to C₅ are capacitances detected by the left detection electrode 11a-the center detection electrode 15a and Cₘₐₓ is the largest capacitance. Multiplication by 100 is used to express the calculated value C_{A} in percentage (%), but it is not necessary to multiply. That is, the following equation (2) may be used.

Calculated value C_{A}=Cₘₐₓ/(C₁+C₂+C₃+C₄+C₅) (2)

When the calculated value C_{A} is obtained by the equation (1), the capacitance threshold value Th is preferably set within, e.g., a range of 70≤Th≤90, more preferably, within a range of 75<3 Th≤85. The capacitance threshold value Th in the present embodiment is 80, as an example.

Meanwhile, when the calculated value C_{A} is obtained by the equation (2) as a modification, the capacitance threshold value Th is preferably set within, e.g., a range of 0.7≤Th≤0.9, more preferably, within a range of 0.75≤Th≤0.85. The capacitance threshold value Th when using the equation (2) is 0.8, as an example.

As a further modification, the calculated value C_{A} may be obtained by the following equation (3).

Calculated value C_{A}=(Sum of capacitances)−(Largest capacitance Cₘₐₓ) (3)

When the calculated value C_{A} is obtained by the equation (3), the capacitance threshold value Th is preferably set within a range of 10-30% of the sum of capacitances, more preferably, within a range of 15-25%. The capacitance threshold value Th in this case is set to 20% of the sum of capacitances, as an example. The sum of capacitances here is determined based on simulations or experiments. When the sum of capacitances is, e.g., 300, the capacitance threshold value Th is 20% of 300, i.e., 60. The control unit 3 causes the image to be displayed when the calculated value C_{A} obtained by the equation (3) is not more than the capacitance threshold value Th, and does not cause the image to be displayed when more than the capacitance threshold value Th.

Next, the calculated value C_{A} obtained by the equation (1) will be described in reference to FIGS. 3A to 4C. In this regard, when a touch operation is not performed, the control unit 3 calibrates so that the left detection electrode 11a-the center detection electrode 15a detect zero as the capacitances C₁-C₅.

In the case where a touch operation is detected by a single detection electrode When a touch operation is detected by a single detection electrode (=the left detection electrode 11a) as shown in FIG. 3B, the capacitance C₁ detected by the left detection electrode 11a is larger than the capacitances C₂ to C₅ as shown in FIG. 4A. When the capacitance C₁ is 100 and the other capacitances C₂ to C₅ are zero, C₁ is used as the largest capacitance Cₘₐₓ in the equation (1) and the calculated value C_{A} is obtained as follows.

Calculated value C_{A}=C₁/(C₁+C₂+C₃+C₄+C₅)×100=100

The obtained calculated value C_{A} is larger than the capacitance threshold value Th (=80). Therefore, the control unit 3 causes the image to be displayed by determining that the left detection electrode 11a detected a touch operation, i.e., a touch operation was performed on the left push switch 11.

In the case where a touch operation is detected by plural detection electrodes When a touch operation is detected by plural detection electrodes (=the left detection electrode 11a, the upper detection electrode 13a and the center detection electrode 15a) as shown in FIG. 3C, the capacitance C₁ detected by the left detection electrode 11a, the capacitance C₃ detected by the upper detection electrode 13a and the capacitance C₅ detected by the center detection electrode 15a are larger than the capacitances C₂ and C₄ as shown in FIG. 4B. When the capacitance C₁ is 100, the capacitance C₃ is 70, the capacitance C₅ is 80 and the other capacitances C₂ and C₄ are zero, C₁ is used as the largest capacitance Cₘₐₓ in the equation (1) and the calculated value C_{A} is obtained as follows.

Calculated value C_{A}=C₁/(C₁+C₂+C₃+C₄+C₅)×100=40

The obtained calculated value C_{A} is smaller than the capacitance threshold value Th (=80). Therefore, the control unit 3 does not cause the image to be displayed by determining that it is not an intentional touch operation.

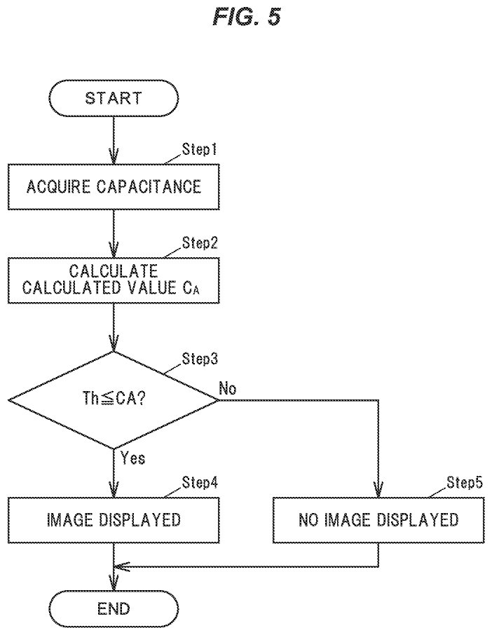

Next, an operation of the operation device 1 in the present embodiment to detect a touch operation will be described along with the flowchart in FIG. 5.

### (Operation)

The control unit 3 of the operation device 1 periodically acquires capacitances S₁ₐ-S₅ₐ from the left detection electrode 11athe center detection electrode 15a (Step 1). Next, the control unit 3 calculates the calculated value C_{A} using the acquired capacitances S₁ₐ-S₅ₐ and the equation (1) (Step 2).

The control unit 3 compares the obtained calculated value C_{A} to the capacitance threshold value Th stored in the storage unit 2. When the calculated value C_{A} is not less than the capacitance threshold value Th (Step 3: Yes), the control unit 3 causes the image, which corresponds to the detection electrode detected the largest capacitance Cₘₐₓ, to be displayed upon the determination that a touch operation was performed (Step 4) and then ends the image display process associated with the touch operation. At this stage, the control unit 3 outputs the operation information S₆, which includes information of the push switch detected as being touch-operated, to an electronic device. Based on the operation information S6, the electronic device displays an image corresponding to the detection electrode that detected the largest capacitance Cₘₐₓ.

Meanwhile, when the calculated value C_{A} is smaller than the capacitance threshold value Th in Step 3 (Step 3: No), the control unit 3 does not cause an image associated with the touch operation to be displayed upon determination that the detected touch operation is unintentional (Step 5) and then ends the process. At this stage, the control unit 3 does not output the operation information S₆ so that the image associated with the unintentional touch operation is not displayed.

### Effects of the Embodiment

The operation device 1 in the present embodiment can suppress incorrect display. In particular, when a proportion of the largest capacitance Cₘₐₓ in the sum of capacitances is larger than proportions of the other capacitances, i.e., when a proportion of the largest capacitance Cₘₐₓ in the sum of capacitances is not less than the capacitance threshold value Th, the operation device 1 determines that a touch operation is performed on the push switch corresponding to the detection electrode that detected the largest capacitance Cₘₐₓ. Therefore, even when the user unintentionally touches during driving and plural detection electrodes detect a touch operation, the operation device 1 accurately determines whether or not it is an intentional touch operation, and it is thus possible to suppress a phenomenon that an image displayed upon detection of the touch operation is incorrect display, as compared to when a touch operation is determined based on only capacitance that is not less than a touch operation determination threshold value.

The operation device 1 suppresses determination of unintentional touch operation and thus can suppress unnecessary movement of eyes due to unintentional incorrect display.

The operation device 1 does not cause the image to be displayed when determining that it is an unintentional touch operation, and causes the image to be displayed when determining that it is an intentional touch operation. Therefore, as compared to when such a configuration is not adopted, movement of eyes to check the currently touching position is suppressed and it is also easy to perform an operation on an intended push switch, hence, operability is improved.

The operation device 1 is configured as a push switch in which the operating portion receives a push operation. Therefore, as compared to when such a configuration is not adopted, it is easy to operate for the user who is holding the steering wheel 80.

The operation device 1 detects a touch operation by detection electrodes that constitute a self-capacitance touch sensor. Therefore, as compared to when such a configuration is not adopted, the structure is simple and the processing is also easy, hence, it is possible to suppress the cost.

As another embodiment, the operation device 1 may additionally have a calculation threshold value used for calculation of the calculated value C_{A}. In this case, the control unit 3 calculates the calculated value C_{A} when capacitance of not less than the calculation threshold value is detected. Then, the control unit 3 compares the calculated value C_{A} to the capacitance threshold value Th and determines whether or not the touch operation is an intentional touch operation.

Although some embodiment and modifications of the invention have been described, these embodiment and modifications are merely examples and the invention according to claims is not to be limited thereto. These new embodiment and modifications may be implemented in various other forms, and various omissions, substitutions and changes, etc., can be made without departing from the gist of the invention. In addition, all combinations of the features described in these embodiment and modifications are not necessary to solve the problem of the invention. Further, these embodiment and modifications are included within the scope and gist of the invention and also within the invention described in the claims and the range of equivalency.

### REFERENCE SIGNS LIST

1 OPERATION DEVICE
2 STORAGE UNIT
3 CONTROL UNIT
8 VEHICLE
9a LEFT HAND
9b RIGHT HAND
10 OPERATING PORTION
11-15 LEFT PUSH SWITCH-CENTER PUSH SWITCH
11a-15a LEFT DETECTION ELECTRODE-CENTER DETECTION ELECTRODE
11b-15b LEFT SWITCH PORTION-CENTER SWITCH PORTION
21-25 LEFT OPERATING REGION-CENTER OPERATING REGION
80 STEERING WHEEL
82 MAIN DISPLAY
84 SUB-DISPLAY
86 HEAD-UP DISPLAY
90 THUMB
100 BEZEL
100a OPENING
101 SUBSTRATE
101a FIXED ELECTRODE
102 RUBBER SHEET
103 RUBBER DOME
103a MOVABLE ELECTRODE
110-150 OPERATING KNOB
150a FRONT SURFACE
150b BACK SURFACE
150c STOPPER
801 SPOKE PORTION
802 SPOKE PORTION
860, 861, 861a-861e, 862a-862e IMAGE

1. An operation device, comprising:
an operating portion comprising a plurality of adjacent operating regions;
a plurality of detection portions that are arranged on the operating portion so as to correspond to the plurality of operating regions to detect contact and each output a detection value; and
a determination unit that calculates a calculated value from a sum of the obtained detection values and the largest detection value among the obtained detection values, compares the calculated value to a predetermined threshold value, and thereby decides whether or not to display an image on an electrically connected display device, the image being associated with the detection portion that output the largest detection value.

2. The operation device according to claim 1, wherein the determination unit causes the image to be displayed when the calculated value obtained by dividing the largest detection value by the sum of the detection values is not less than the predetermined threshold value.

3. The operation device according to claim 1, wherein the determination unit does not cause the image to be displayed when the calculated value obtained by dividing the largest detection value by the sum of the detection values is less than the predetermined threshold value.

4. The operation device according to claim 1, wherein the operating portion comprises a plurality of operating knobs corresponding to the plurality of operating regions and receiving a push operation, and a plurality of switch portions detecting the push operation performed on the operating knobs.

5. The operation device according to claim 1, wherein the plurality of detection portions comprise a plurality of detection electrodes that constitute a self-capacitance touch sensor, and the detection value is capacitance.

6. The operation device according to claim 5, wherein the operating portion is disposed on a spoke portion of a steering wheel of a vehicle.

7. The operation device according to claim 5, wherein the operating portion comprises two operation portions disposed in bilateral symmetry on a spoke portion of a steering wheel of a vehicle, and the two operation portions each comprise at least two of the operation regions.

8. The operation device according to claim 5, wherein the operating portion comprises two operation portions disposed in bilateral symmetry on a spoke portion of a steering wheel of a vehicle, and the two operation portions each comprises at least two of the operation regions disposed in bilateral symmetry.
